(19) United States
(12) Patent Application Publication
(10) Pub. No.: US 2026/0239660 A1
(43) Pub. Date: Aug. 13, 2026

(54) Complementary Depletion Transistor Technology

(71) Applicant: Gil Mordehi Asa, Zichron Yaakov (IL)

(72) Inventor: Gil Mordehi Asa, Zichron Yaakov (IL)

(21) Appl. No.: 19/051,218

(22) Filed: Feb. 12, 2025

(51) Int. Cl. H10D 30/63; G11C 11/412; H03K 17/687; H10D 30/62; H10D 84/01; H10D 84/85

(52) U.S. Cl. CPC H10D 30/637; H03K 17/6872; H10D 30/6211; H10D 84/0191; H10D 84/0193; H10D 84/853; H10D 84/859; G11C 11/412

(57) ABSTRACT

A pair of N and P channel depletion MOFSETs (NDEP and PDEP respectively) are disclosed. Each MOFSET may have a FINFET geometry. The depletion mode MOSFETs may have properties facilitating reduction of the number of transistors in a MOSFET circuits. A two-transistor retention element is disclosed. For example, the gate of an NDEP may be linked (e.g., connected by a conductor) to the gate of a PDEP to form a reverse bias diode. A single transistor pass gate is disclosed. For example, a single PDEP and/or NDEP may be formed into a pass gate. A 2-transistor retention element combined with a single transistor pass gate is disclosed to form a three transistor Static Random Access Memory (SRAM).

### FIELD AND BACKGROUND OF THE INVENTION

The present invention, in some embodiments thereof, relates to a 3D transistor and, more particularly, but not exclusively, to a 3D depletion transistor.

VLSI (Very Large-Scale Integration) is an entity that has a constant scale down drive. This is the meaning of the term “Very Large-Scale Integration”. The technological ability to integrate billions of CMOS transistors into the same silicon die is constantly reducing the cost per transistor while simultaneously increasing the ROI (Return On Investment). The dominant way to enlarge the number of transistors is simply done by scaling down the dimensions of the transistor device. This tendency has had a remarkable success along the last few decades, but as new higher density technologies emerge, it is becoming harder to keep the pace of the industrial requirements.

The increasing challenge of the scale down limitations is convincing the manufacture experts to look for new directions. For example: 3D electronics and continuous effort to turn analog blocks into digital blocks

### SUMMARY OF THE INVENTION

According to an aspect of some embodiments of the invention, there is provided an n-channel depletion mode transistor including: a P-doped substrate; a fin protruding from the P-doped substrate the fin including a P-doped base layer in contact with the P-doped substrate a N doped channel in contact with the P-doped base; a gate in proximity to an intermediate location on the N-doped channel and electrically insulated from the N-doped channel; a source in electrical contact with the N-doped channel on a first side of the intermediate location and a drain in electrical contact with the N-doped channel on a second side of the intermediate location, opposite first side.

According to some embodiments of the invention, the gate is a Gate All Around the channel (GAA).

According to some embodiments of the invention, a plurality of the fins are arranged in parallel on a chip.

According to some embodiments of the invention, for Vb=Vg=0 the transistor is in an OFF state wherein Vg is gate voltage, and Vb is P-doped substrate voltage.

According to some embodiments of the invention, 0<Vs≠Vd<V+ and Vbd is breakdown voltage, Vs is Source voltage, Vd is Drain voltage.

According to some embodiments of the invention, for Vg=V+ the N-doped channel depletion mode transistor is in an ON state.

According to some embodiments of the invention, a resistance to electrical current between the source and the drains in the OFF state is at least 10\hat{ }4 times a resistance to electrical current between the source and the drains in the ON state.

According to some embodiments of the invention, the N-channel depletion mode transistor where in the ON state there is significant current between the source and the drain for a positive voltage potential 0<V+<Vbd between the source and the drain.

According to some embodiments of the invention, the N-channel mode transistor is configured to function as a single-transistor pass gate.

According to an aspect of some embodiments of the invention, there is provided a p-channel depletion mode transistor including: an N-doped substrate; a fin protruding from the N-doped substrate the fin including a N-doped base layer in contact with the N-doped substrate a P doped channel in contact with the N-doped base; a gate in proximity to an intermediate location on the P-doped channel and electrically insulated from the P-doped channel; a source in electrical contact with the P-doped channel on a first side of the intermediate location and a drain in electrical contact with the P-doped channel on a second side of the intermediate location, opposite first side.

According to some embodiments of the invention, the gate is a Gate All Around the channel (GAA).

According to some embodiments of the invention, a plurality of the fins are arranged in parallel on a chip.

According to some embodiments of the invention, for Vb=Vg=V+ the transistor is in an OFF state wherein Vg is gate voltage, and Vb is N-doped substrate voltage.

According to some embodiments of the invention, 0<Vs≠Vd<V+ and Vbd is breakdown voltage, Vs is Source voltage, Vd is Drain voltage.

According to some embodiments of the invention, for Vg=0 the P-channel depletion mode transistor is in an ON state.

According to some embodiments of the invention, a resistance to electrical current between the source and the drains in the OFF state is at least 10\hat{ }4 times a resistance to electrical current between the source and the drains in the ON state.

According to some embodiments of the invention, the P-channel depletion mode transistor where in the ON state there is significant current between the source and the drain for a positive voltage potential 0<V+<Vbd between the source and the drain.

According to some embodiments of the invention, the P-channel mode transistor is configured to function as a single-transistor pass gate.

According to an aspect of some embodiments of the invention, there is provided a MOFSET circuit where Vds is a voltage potential between 0 and V+ and less than Vbd including: a first transistor configured to be in an ON state for gate voltage of the first transistor V1g=V+ and an OFF state for V1g=0 and to have a break down voltage greater than V+; a second transistor configured to in an ON state for a gate voltage of the second transistor V2g=0 and an OFF state V2g=V+ and to have a break down voltage greater than V+.

According to some embodiments of the invention, where the circuit is configured as a two-transistor buffer.

According to some embodiments of the invention, where the circuit is configured as a two-transistor inverter.

According to some embodiments of the invention, where the circuit is configured as a three-transistor SRAM.

According to some embodiments of the invention, where the circuit is configured as an eight-transistor dynamic DFF.

According to some embodiments of the invention, where the circuit is configured as an twelve-transistor static DFF.

According to some embodiments of the invention, where the circuit is configured as a two-transistor retention element.

According to some embodiments of the invention, the first and second transistors are depletion mode MOFSETS.

According to some embodiments of the invention, the first and second transistors are FINFETs.

According to some embodiments of the invention, the first transistor is an NDEP.

According to some embodiments of the invention, the second transistor is an PDEP.

According to an aspect of some embodiments of the invention, there is provided a method of building a MOFSET circuit where Vads is a voltage potential between 0 and V+ and less than Vbd including: supplying a first transistor configured to be in an ON state for gate voltage of the first transistor V1g=V+ and an OFF state for V1g=0 and to have a break down voltage greater than V+; supplying a second transistor configured to in an ON state for a gate voltage of the second transistor V2g=0 and an OFF state V2g=V+ and to have a break down voltage greater than V+.

According to some embodiments of the invention, the method building a two-transistor buffer by shorting a gate of the first transistor to a gate of the second transistor as an input lead, shorting a drain of the first transistor to a drain of the second transistor as an output lead, connecting a source of the first transistor to a V+voltage and connecting a source of the second transistor to a 0 voltage.

According to some embodiments of the invention, the method further includes building a two-transistor inverter by shorting a gate of the first transistor to a gate of the second transistor as an input lead, shorting a drain of the first transistor to a drain of the second transistor as an output lead, connecting a source of the first transistor to a 0 voltage and connecting a source of the second transistor to a V+ voltage.

According to some embodiments of the invention, the method further includes: building a two-transistor retention element by shorting the gates and drains of the first and second transistors together supplying a voltage of V+ to a source lead of the first transistor and supplying a voltage of 0 to a source lead of the second transistor.

According to some embodiments of the invention, the first and second transistors are depletion mode MOFSETS.

According to some embodiments of the invention, the first and second transistors are FINFETs.

According to some embodiments of the invention, the first transistor is an NDEP.

According to some embodiments of the invention, the second transistor is an PDEP.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1A is a block diagram illustrating the structure of a depletion mode transistor in accordance with an embodiment of the current invention;

FIG. 1B is a symbolic diagram of a P-Channel depletion mode transistor (PDEP) pass gate in accordance with an embodiment of the current invention;

FIG. 1C is a symbolic diagram of a N-Channel depletion mode transistor (NDEP) pass gate in accordance with an embodiment of the current invention;

FIG. 2A is a perspective view of a FINFET structure for a depletion mode transistor in accordance with an embodiment of the current invention;

FIG. 2B is a cross-sectional view of the 3D structure of the FINFET depletion mode transistor of FIG. 2A along line A-A′ in accordance with an embodiment of the current invention;

FIG. 2C illustrates a cross section (across line B-B′ of FIG. 2A) of 2 lines of parallel depletion MOSFETs in accordance with an embodiment of the current invention;

FIG. 3 illustrates a cross section of a bulk FET depletion transistor in accordance with an embodiment of the current invention;

FIG. 4A is a schematic illustration of a FINFET depletion transistor in an ON state in accordance with an embodiment of the current invention. In some embodiments;

FIGS. 4B and 4C are a schematic illustrations of a FINFET depletion transistor in an OFF state in accordance with an embodiment of the current invention;

FIG. 5 is a flow chart illustration of a manufacturing a MOSFET in accordance with an embodiment of the current invention;

FIG. 6 is a simplified mathematical model for the behavior of a depletion mode MOSFET in accordance with embodiments of the current invention;

FIGS. 7A-7C are graphs illustrating behavior of depletion mode transistors in a predicted by the model of FIG. 6;

FIGS. 8A and 8B illustrate a 2-transistor retention element 801 in accordance with an embodiment of the current invention;

FIG. 8C illustrates a symbolic transistor circuit 855 in accordance with an embodiment of the current invention;

FIGS. 9A and 9B illustrate embodiments of a 3 transistor SRAM (Static Random Access Memory) in accordance with an embodiment of the current invention;

FIG. 10A illustrates a two-transistor inverter in accordance with an embodiment of the current invention;

FIG. 10B illustrates a two-transistor inverter in accordance with an embodiment of the current invention;

FIG. 11 illustrates a four-transistor single to differential 1160 schematic in accordance with an embodiment of the current invention;

FIGS. 12A and 12B illustrates a dynamic D Flip Flop (DFF 1261a) compact D Flip Flop (D-FF 1261b) in accordance with embodiments

FIG. 13 illustrates an XNOR gate 1362 in accordance with an embodiment of the current invention; and

FIG. 14 illustrates a type A voltage divider in accordance with an embodiment of the current invention.

### DESCRIPTION OF SPECIFIC EMBODIMENTS OF THE INVENTION

### OVERVIEW

The present invention, in some embodiments thereof, relates to a 3D transistor and, more particularly, but not exclusively, to a 3D depletion transistor.

In some embodiments, the current invention includes a novel transistor that facilitates formation of useful circuits with reduced number of transistors used compared to conventional circuits.

In some embodiments, a transistor may include a 3D structure. For example, the transistor may have multiple layers of semiconductor of different doping. Optionally, a channel is controlled by a gate. Optionally, at least part of the channel may be positioned between the gate and a well. Additionally or alternatively, the 3D structure may include a Gate All Around the channel (GAA). Optionally, the channel may be partially isolated from a well. For example, a base of the channel may be in contact with the well and/or other parts of the channel may be isolated from the well except through the base. For example, the channel may include a fin structure with a base contacting the well and the rest of the channel protruding away from the well. The channel optionally has a first doping (e.g., n-type or p-type) at the base and/or projecting partially out from the well. Optionally, the doping of the base of the channel in contact with the well may be the same as the doping of the well. For example, the transistor may have a Finfet geometry.

In some embodiments, portions of the channel projecting from the base away from the well may have an opposite doping from the base. For example, a PDEP (P-type depletion transistor) may include an N-well with an additionally P-layer on top of the base of the channel. For example, an NDEP (N-type depletion transistor) may include a P-well with an additionally N-layer on top of the base of the channel. Optionally, a source and/or drain include portions doped opposite the well. For example, the source and/or drain may include more heavily doped then additionally layer on top of the base layer of the channel. Optionally, the source and/or gate are in contact with the additionally layer of the channel. Optionally, the additionally layer of the channel is insulated from other layers except from the well beneath it.

In some embodiments, a two-transistor retention element may be constructed of two depletion mode MOSFETs, for example, the gate of an NDEP may be linked (e.g., connected by a conductor) to the gate of a PDEP to form a reverse bias diode.

In some embodiments a transistor (e.g., a single PDEP and/or a single NDEP) may be formed into a pass gate. Optionally, a single transistor pass gate will be combined with a 2-transistor retention element to form a three transistor Static Random Access Memory (SRAM). Additionally or alternatively, two 3 transistor SRAMs may be combined to form a 12-transistor static D-flip-flop (static D-FF) and/or to form an 8-transistor dynamic D-FF. In some embodiments, an NDEP and/or PDEP inverter and/or buffer may be combined to form a 4-transistor single to differential circuit. For example, the single to differential may include reduced and/or negligent leakage. Optionally, various complex gates and/or amplifiers may be formed from the combined NDEP and/or PDEP transistors.

In some embodiments, an NDEP and/or a PDEP may be integrated with convention enhanced mode NMOS and/or CMOS process. For example, the additional P-layer/N-layer of the PDEP/NDEP transistor may be facilitated in production with two additional masks. Alternatively or additionally, the NDEP and/or PDEP may formed with the number of masks identical to the ordinary Finfet process.

### EXEMPLARY EMBODIMENTS

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

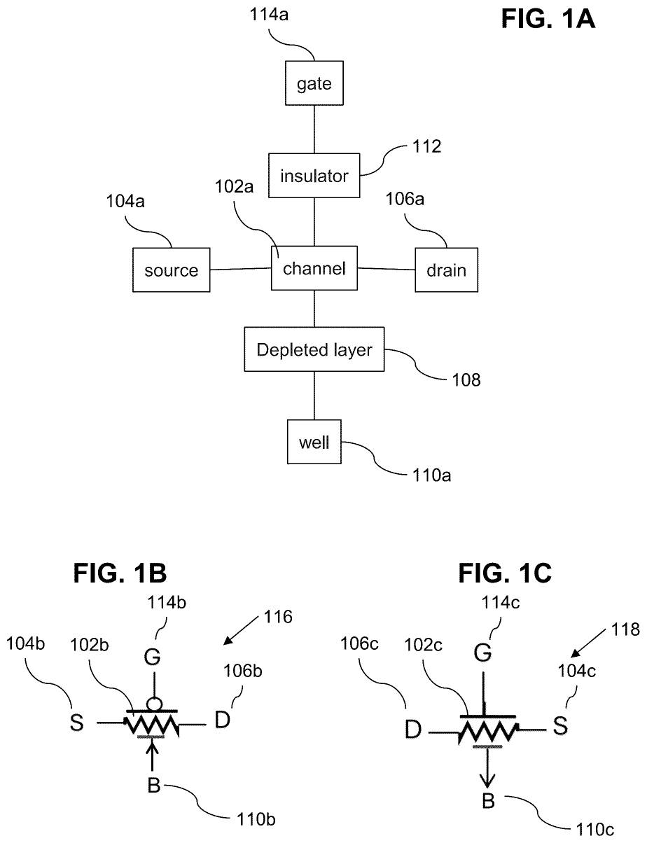

Referring now to the drawings, FIG. 1A is a block diagram illustrating the structure of a depletion mode transistor in accordance with an embodiment of the current invention. In some embodiments a depletion mode transistor includes a semiconductor channel 102a connecting between a source 104a and a drain 106a. Optionally, the source 104a, the drain 106a and the channel 102a will all have a similar doping. Additionally or alternatively, the doping of the source 104a and/or the drains 106a may be more heavily doped than the channel 102a. Optionally, electrical current may be conducted across the channel 102a between the source 104a and the drain 106a.

In some embodiments, the semi-conductor channel 102a will contact a well 110a. Optionally, the well 110a will be doped with a doping opposing the doping of the channel 102a. In some embodiments, the well 11a may include the substrate. In some embodiments, the opposing doping's of well 110a and the channel 102a will create a depletion layer 108 between the well 110a and the channel 102a. For example, the depletion layer may electrically insulate between the channel 102a and the well 110a. Additionally or alternatively, the channel 102a may be insulated from any and/or all other layers and/or structures in the transistor and/or device.

In some embodiments, a get 114a will be positioned to control channel 102a. For example, gate 114a may be positioned over channel 102a and/or separated from channel 102a by an insulator 112. For example, a charge on gate may control the electrical conductance of the channel 102a and/or the resistance to passing electrical current between the source 104a and the drain 106a.

In some embodiments, a depletion transistor of the current invention includes a distinct channel having an opposite doping of a well (e.g., a N-channel in contact with a P-well and/or a P-channel in contact with a N-well). Optionally, the interaction between the well and the channel may facilitate depleting between 1 to 10% and/or between 10 to 30% and/or between 30 to 50% and/or between 50% to 75% and/or more than 50% of the deeper part of the channel. Optionally for at least one operating gate voltage and/or combination of voltages of the gate 114a, the source 104a and the drain 106a a depleted zone will fill the entire channel 102a at some location between the source 104a and the drain 106a and/or electrical conduction in the channel 102a will be fully blocked by a depleted zone intervening between the source 104a and the drain 106a for potential difference below a break down potential.

FIG. 1B is a symbolic diagram of a P-Channel depletion mode transistor (PDEP) pass gate in accordance with an embodiment of the current invention. For example, for a PDEP 116 the channel 102b, the source 104b and the drain 106b may all be doped with a p-type doping (e.g., doped with an electron acceptor). For example, for PDEP 116 the well 110b is optionally doped with an electron donor (e.g., an n-doping). A gate 114b, optionally, controls the channel 102b.

For the current disclosure, the following symbols will be used: the potential difference between the gate and the source V_{GS}, the potential difference between the gate and the drain V_{GD}, the potential difference between the drain and the source V_{DS}, the potential difference between the gate and the well V_{GB}, the potential difference between the drain and the well V_{DB}, and the potential difference between the source and the well V_{SB} have absolute value less than a breakdown voltage V_{b}, then for the following combinations of values where V_{D} is the voltage potential at the drain, V_{S} is the voltage potential at the source, V_{G} is the voltage potential at the gate, 0<V₊<V_{b}.

In some embodiment of the current invention a PDEP 116 may be used as a pass gate. For example, with the well 110b voltage (V_{B}) biased positive (V_{B}=V₊). In some embodiments and/or with some well biases the PDEP serve as a pass gate and/or display some or all of the following behaviors:
If VD=0, VS=V+, and VG=0, then PDEP will be ON.
If VD=V+, VS=0, and VG=0, then PDEP will be ON.
If VD=V+, VS=0, and VG=V+ then PDEP will be OFF.
If VD=0, VS=V+, and VG=V+ then PDEP will be OFF.
If VG~½ V+, then PDEP will be saturated.

FIG. 1C is a symbolic diagram of a N-Channel depletion mode transistor (NDEP) pass gate in accordance with an embodiment of the current invention. For example, for an NDEP 118 the channel 102c, the source 104c and the drain 106c may all be doped with an n-type doping (e.g., doped with an electron donor). For example, for NDEP 118 the well 110c is optionally doped with an electron acceptor (e.g., a p-doping). A gate 114c, optionally, controls the channel 102c.

In some embodiment of the current invention a depletion mode transistor (e.g., NDEP 118 and/or PDEP 116) may be used as a pass gate. For example, the pass gate may have a low resistance in the ON state (e.g., the channel may tend towards being conductive). The pass gate may include a high resistivity in the OFF state (e.g., the channel may be restricted by the bias on the gate and/or by its contact with the oppositely doped well and/or due to the bias on the well). For example, for NDEP 118 a zero or negative bias on the well 110c may deplete and/or increase the resistance in the lower portion of the channel 102c improving performance (e.g., increasing channel resistance and/or decreasing the gate bias) in the OFF state. Optionally, a pass gate may be used as capacitor divider “voltage reference,” for example, when its output is connected only to other transistor gates.

In some embodiment of the current invention a PDEP 116 may be used as a pass gate. For example, with the well 110c voltage (V_{B}) biased negative (or zero) (V_{B}=0). In some embodiments and/or with some well biases the PDEP serve as a pass gate and/or display some or all of the following behaviors:
If VD=0, VS=V+, and VG=0 then NDEP will be OFF.
If VD=V+, VS=0, and VG=0 then NDEP will be OFF.
If VD=V+, VS=0, and VG=V+ then NDEP will be ON.
If VD=0, VS=V+, and VG=V+ then NDEP will be ON.
If VG~½ V+, then NDEP will be saturated.

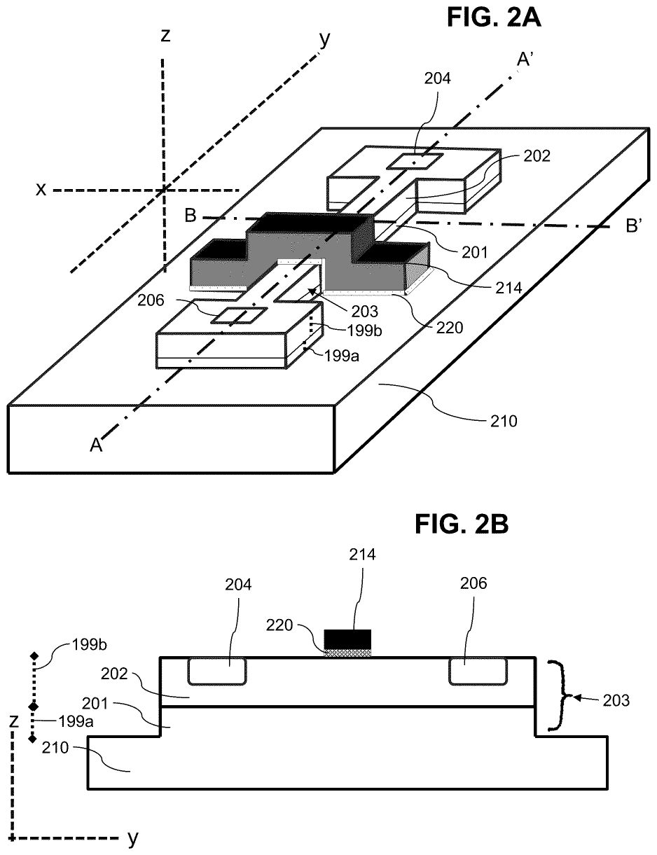

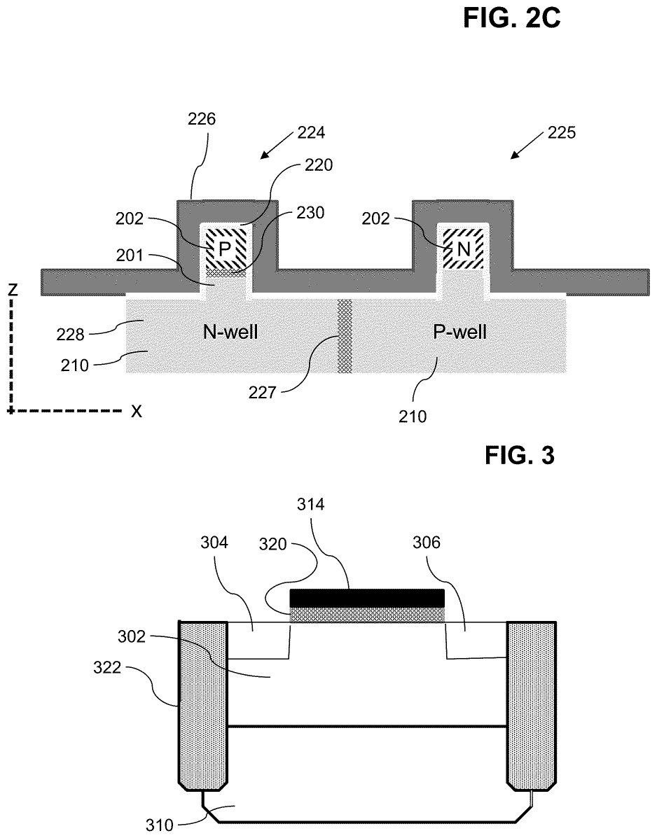

FIG. 2A is a perspective view of a FINFET structure for a depletion mode transistor in accordance with an embodiment of the current invention. The structure of the Finfet may differ from planar MOS transistors by some or all of the following characters:
1. In some embodiments the FINFET has a 3D structure with Gate 214 All Around the channel 202 (GAA) and/or a fin 203.
2. Optionally the fin structure includes an upper channel 202 with the opposite doping of the well 210 and/or a lower portion of the fin 203 may include a portion 201 with the same doping of the well 210 and/or that is an extension upward from the well 210 (under the gate).
3. The Source 204 and/or Drain 206 may be heavily doped with the opposite type of the well 210.
4. The Finfet optionally includes many same fins 203 in parallel (e.g., as seen in FIGS. 2C and/or 4A-4D).
5. Additional implants may be added over common transistors.

In some embodiments, a layer of insulator (e.g., a dielectric e.g., an oxide) interrupts between the gate 214 and the channel 202 and/or the gate 214 and the lower portion 201of the fin 203 and/or the gate 214 and the well 210.

FIG. 2B is a cross-sectional view of the 3D structure of the FINFET depletion mode transistor of FIG. 2A along line A-A′ in accordance with an embodiment of the current invention.

In some embodiments, the channel 202 includes an upper layer of the fin 203 with opposite doping to the well 210. Optionally, a lower portion 201 of the fin 203 is of a same doping as the well 210 and/or an extension of the well 210. Optionally, fin 203 has additional layer on top (e.g., channel 202).

For example, for an embodiment of a PDEP transistor the well 210 and the lower portion 201 of the fin 203 will be N-doped while the upper layer of the fin 203 (e.g., the channel 202) will be P-doped. Additionally or alternatively, the source 204 and/or drain 206 may be P-doped and/or have a stronger doping than the channel 202.

For example, for an embodiment of an NDEP transistor the well 210 and/or the lower portion 201 of the fin 203 will be P-doped while the upper layer of the fin 203 (e.g., the channel 202) will be N-doped. Additionally or alternatively, the source 204 and/or drain 206 may be N-doped and/or have a stronger doping than the channel 202.

In some embodiments, the upper portion of the fin 203 (e.g., the channel 202) is isolated from any neighbor layer except the lower portion 201 of the fin 203 and/or the well 210. Additionally or alternatively the source 204 and/or drain 206 are isolated from any neighbor layer except the channel 202. Alternatively or additionally, source 204 and/or drain 206 may contact the lower portion 201 of the fin 203 and/or the well 210. Additionally or alternatively, the lower portion 201 of the fin 203 is isolated from any neighbor layer except the channel 202 and/or the well 210. Alternatively or additionally, the lower portion 201 may contact the source 204 and/or the drain 206. For example, the channel 202 and the lower portion 201 of the fin form a reverse bias diode. For example, the channel 202 and the well 210 form a reverse bias diode.

FIG. 2C illustrates a cross section (across line B-B′ of FIG. 2A) of 2 lines of parallel depletion MOSFETs in accordance with a embodiment of the current invention. For example, a PDEP 224 is positioned on a substrate 228 next to an NDEP 225. Optionally the well of the PDEP 224 is separated from the well of NDEP 225 by a P-N depletion zone 227. Optionally, the channel 202 is separated from the well by a depletion layer 230. Additionally or alternatively, a line of PDEPs 224 may be positioned next to a line of NDEPs 225. The side-by-side PDEP 224 and NDEP 225 may share a gate 226 and/or have separately controlled gates.

FIG. 3 illustrates a cross section of a bulk FET depletion transistor in accordance with an embodiment of the current invention.

In some embodiments, a depletion transistor includes a channel 302 of opposite doping to a well 310. For example, for an embodiment of a PDEP transistor the well 310 will be N-doped while the channel 302 will be P-doped. Additionally or alternatively, the source 304 and/or drain 306 may be P-doped and/or have a stronger doping than the channel 302. For example, for an embodiment of an NDEP transistor the well 310 will be P-doped while the channel 302 will be N-doped. Additionally or alternatively, the source 304 and/or drain 306 may be N-doped and/or have a stronger doping than the channel 302. In some embodiments, a gate 314 is separated from the channel 302 by an insulator 320 (e.g., and oxide layer).

In some embodiments, the channel 302 is isolated from any neighbor layer except the well 310 and/or the source 304 and/or the drain 306. Additionally or alternatively, the source 304 and/or drain 306 are isolated from any neighbor layer except the channel 302. Alternatively or additionally, the source 304 and/or drain 306 may contact the well 310. For example, the channel 302 and the well 310 form a reverse bias diode. An insulator 322 (e.g., an oxide) may insulate the channel 202 from neighboring structures.

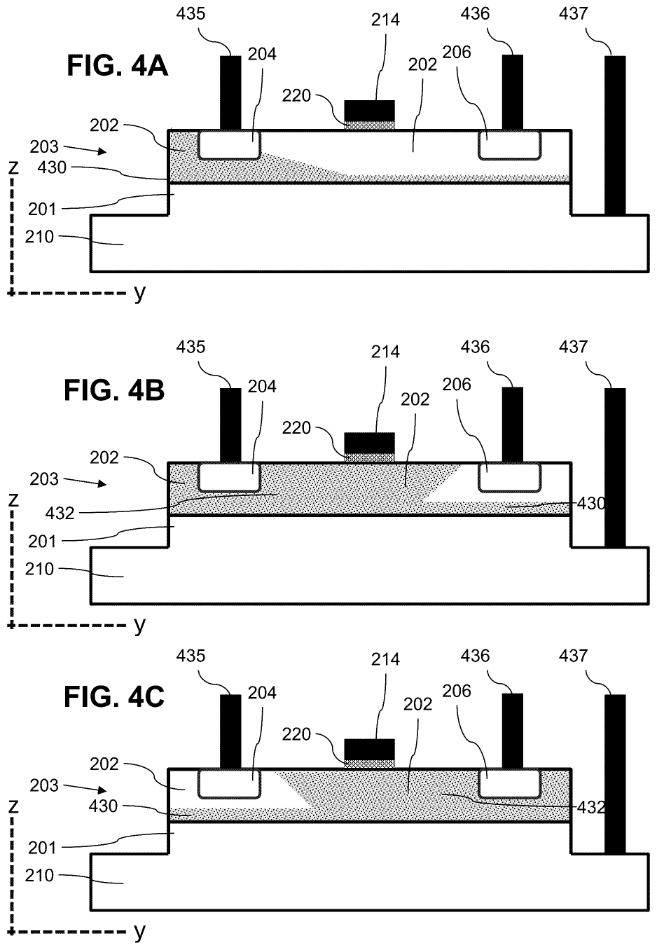

FIG. 4A is a schematic illustration of a FINFET depletion transistor in an ON state in accordance with an embodiment of the current invention. In some embodiments. For example, examples of an ON mode may include
V_{D}=V+, V_{S}=0 and V_{G}=V+for an NDEP will be ON.
V_{D}=0, V_{S}=V+, and V_{G}=V+for an NDEP will be ON.
V_{D}=0, V_{S}=V+, and V_{G}=0, for a PDEP will be ON.
V_{D}=V+, V_{S}=0, and V_{G}=0, for a PDEP will be ON.

In the ON state the channel 202 may provide a highly conductive connection between the source 204 and the drain 206. Optionally, there may be a depleted zone 430 at bottom of the channel 202 (e.g., the side of the channel distant from the gate 214). Optionally, the depleted zone is at the interface between the channel 202 and the lower portion 201 of the fin and/or between channel 202 and the well 210. For example, the opposing doping of the channel 202 with respect to the lower portion 201 of the fin and/or the well 210 results in a p-n junction and/or depleted region at the interface between them. This depletion region may remain even when the MOSFET is in an ON state. Optionally, in the ON state, this region is localized near the interface distant from the gate 214 and/or does not block conduction of current between the source 204 and the drain 206. For example, this may be due to the gate voltage V_{G} facilitating current carriers in the region of the channel 202 between the source 204 and the drain 206. In some embodiments, the presence of the depleted layer 430 and/or the presence of the opposite doped portion 201 will result in the high conductivity region between the source 204 and the sink 206 having a thickness that is less than the thickness of the fin 203. In some embodiments, the presence of the depleted layer 430 will result in the high conductivity region between the source 204 and the sink 206 having a thickness that is less than the thickness 199b of the channel 202.

Also shown in FIGS. 4A-4C are leads of the MOFSET. For example, there is a source lead 435, a drain leads 436 and a base lead 437 biasing the well 210.

FIG. 4B is a schematic illustration of a FINFET depletion transistor in an OFF state in accordance with an embodiment of the current invention. In some embodiments. For example, in FIG. 4B the gate 214 and source 204 have charges that deplete the channel causing the FET to be in an OFF state. For example, the area around the source 204 and between the source 204 and the gate 214 and/or between the source 204 and the well 210 are depleted resulting in a depleted region 432 intervening between the source 204 and drain 206 and/or blocking current between the source 204 and drain 206. Examples of an OFF mode as illustrated in FIG. 4B may include:
V_{D}=V+, V_{S}=0, and V_{G}=0, for an NDEP will be OFF.
V_{D}=0, V_{S}=V+, and V_{G}=V+ then PDEP will be OFF.

FIG. 4C is a schematic illustration of a FINFET depletion transistor in an OFF state in accordance with an embodiment of the current invention. In some embodiments. For example, in FIG. 4C the gate 214 and drain 206 have charges that deplete the channel causing the FET to be in an OFF state. For example, the area around the drain 206 and between the drain 206 and the gate 214 and/or between the drain 206 and the well 210 are depleted resulting in a depleted region intervening between the source 204 and drain 206 and/or blocking current between the source 204 and drain 206. Examples of an OFF mode as illustrated in FIG. 4C may include:
V_{D}=V+, V_{S}=0, and V_{G}=V+for a PDEP will be OFF.
V_{D}=0, V_{S}=V+, and V_{G}=0, for an NDEP will be OFF.

Another case in which an embodiment of a depletion mode MOFSET in accordance with the current invention may include:
V_{G} ~½ V+, then NDEP, PDEP will be saturated.

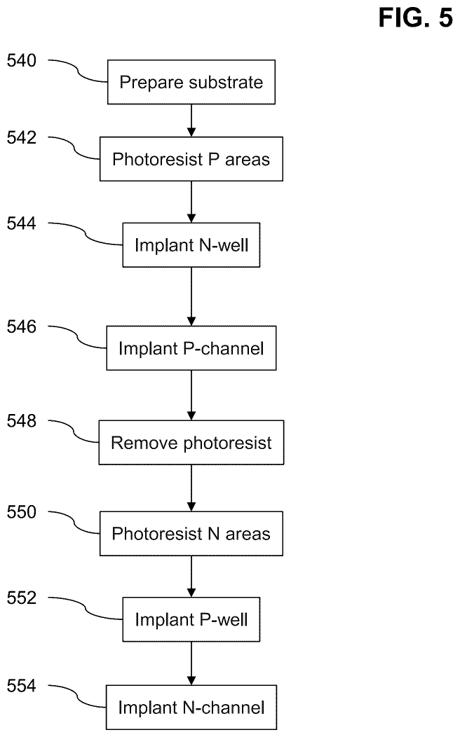

FIG. 5 is a flow chart illustration of a manufacturing a MOSFET in accordance with an embodiment of the current invention. For example, a single substrate may include multiple transistors and/or multiple types of transistors. For example, a single wafer may include both a PDEP and an NDEP. The manufacturing may include one or more of the following:

In some embodiments, a substrate may be prepared 540. For example, the substrate may include Silicon and/or gallium arsenide (GaAs) and/or indium phosphide (InP) and/or Silicon-on-Insulator (SOI). Optionally preparation of the substrate includes cleaning (e.g., using chemical baths, such as RCA) and/or removing contaminants. The substrate surface is optionally polished (e.g., using chemical-mechanical polishing (CMP)). For example, the polishing may facilitate smoothness and/or uniformity of the substrate surface. Light doping may be performed through ion implantation, and/or a thin thermal oxide layer may be grown to serve as the starting point for the gate oxide.

In some embodiments, a photo resist may be applied 542 before doping. For example, before doping N-zones, a photo resist may be applied 542 to zones planned for P doping. The photo resist may optionally be patterned to expose areas to be doped with an N-doping, for example, to exposed areas planned as an N-well (e.g., for a PDEP).

In some embodiments, an N-doping will be applied and/or implanted 544 to exposed areas of the substrate. Optionally the N-doping is annealed.

In some embodiments, layers of P doping will be implanted 546 above layers of N doping. For example, a photo resist may be applied and/or patterned to expose a channel of P doping may be implanted 546 above and/or onto the N-well (e.g., to form a PDEP). For example, the N-well may include a fin (e.g., the fin may have been formed through etching into the substrate). Optionally, the channel may be formed by implanting 546 a P-doping onto an upper portion of the fin (e.g., to form a PDEP FINFET).

In some embodiments, the photo resist may be removed 548 from the substrate (e.g., the area of the P-wells for an NDPEP) and/or a further photo resist may be deposited 550 and/or patterned to expose areas to be doped with P doping (e.g., P-wells of the NDEP),

In some embodiments, a P-doping will be applied and/or implanted 552 to exposed areas of the substrate (e.g., to a P-well of the NDEP). Optionally the N-doping is annealed.

In some embodiments, layers of N doping will be implanted 554 above layers of P doping. For example, N doping that may be implanted 554 above and/or onto the P-well (e.g., to form an NDEP). For example, the P-well may include a fin (e.g., the fin may have been formed through etching into the substrate). Optionally, the channel may be formed by implanting 554 a P-doping onto an upper portion of the fin (e.g., to form a PDEP FINFET).

Some or all of the following parameters may be selected in order to obtain desirable properties (e.g., as defined herein in various embodiments) of an PDEP and/or NDEP in accordance with embodiments of the current invention.:

Selecting the doping levels of the channel (e.g., channel 202, 302), Well (e.g., well 210, 310), lower portion (e.g., portion 201) of the fin (e.g., fin 203) (optionally, the lower portion 201 of the fin 203 may have the same doping as the well 210).

Selecting the working function of the gate (e.g., the voltage levels at the gate under different conditions for the NDEP and/or PDEP).

Selecting the gate dielectric (e.g., insulator 220) thickness and/or the material thereof (e.g., a material with a high dielectric constant K (permittivity) material (e.g., oxide)).

Selecting the surface charge under the gate.

Selecting the channel (e.g., channel 202, 302) thickness 199b (Dₚ for a PDEP and D_{N} for an NDEP) and/or the thickness 119a of the portion 201 of the fin 203 that is doped opposite to the channel 202. In some embodiments the height 199b of the channel 202 and the height 199a of the opposing doped portion 201 add up to the height of the fin 201. In some embodiments, the ratio of the height 199b of the channel 202 to the height 199a of the opposing portion 201 may range between 1000:1 to 100:1 and/or between 100:1 to 10:1 and/or between 1:1 to 1:10 and/or between 1:10 to 1:100. In some embodiments, there may be no opposing portion 201.

Selecting the P-N depletion zone (e.g., zone 430) (e.g., thickness X_{d}N_{w} for an NDEP and/or X_{d}P_{w} (which may be a function of for example the biases on the gate V_{G}, the source V_{S}, The drain V_{D} and/or the well V_{B}).

In some embodiments, the parameters of a NDEP and/or PDEP will be selected to achieve one or more and/or all of the following properties:

In some embodiments the parameters of the PDEP and/or NDEP may be selected so that the value of the gate voltage will be enough to determine if the transistor will be ON or OFF. For example, the parameters of the PDEP and NDEP may be synchronized so that the same set of gate voltages (V+, 0, ½ V+), when applied to the gate, will achieve the desired performance of both the PDEP and NDEP. For example, a zero voltage (‘0’) may be selected that, when applied to the gate, sets the NDEP transistor to OFF (e.g., because the electrons will be pushed away from the gate till a depletion layer under the gate will be thick enough to overlap the depletion level of the P-well PN junction and/or the channel will be totally blocked by depletion). Additionally or alternatively, the V+ (‘1’) voltage may be selected to be enough to cut the PDEP gate to OFF (e.g., because the holes will be pushed away from the gate till a depletion layer under the gate will be thick enough to overlap the depletion level of the N-well PN junction, and the channel will be totally blocked by depletion). Additionally or alternatively, the, V+ (‘1’) may be selected to, when applied to the gate, produce a high conductance between the source of the and the drain of the NDEP (e.g., by pulling electrons towards the gate, forming a conduction channel). Additionally or alternatively, the zero voltage (‘0’) may be selected that when applied to the gate forms a highly conductive channel between the source and the drain in the PDEP. For example, the ‘0’ gate voltage for the PDEP will pull holes towards the gate, forming a conduction channel. Additionally or alternatively, a value for ½ V+ applied to the gate may force the PDEP and/or NDEP transistor into saturation.

In some embodiments, operational and process parameters may be controlled to achieve NDEP/PDEP transistors that have the following properties:
For VDS between 0 and V+,
For VG=0 NDEP is cut off and the PDEP is ON.
For VG=V+ PDEP is cut off and the PDEP is ON.

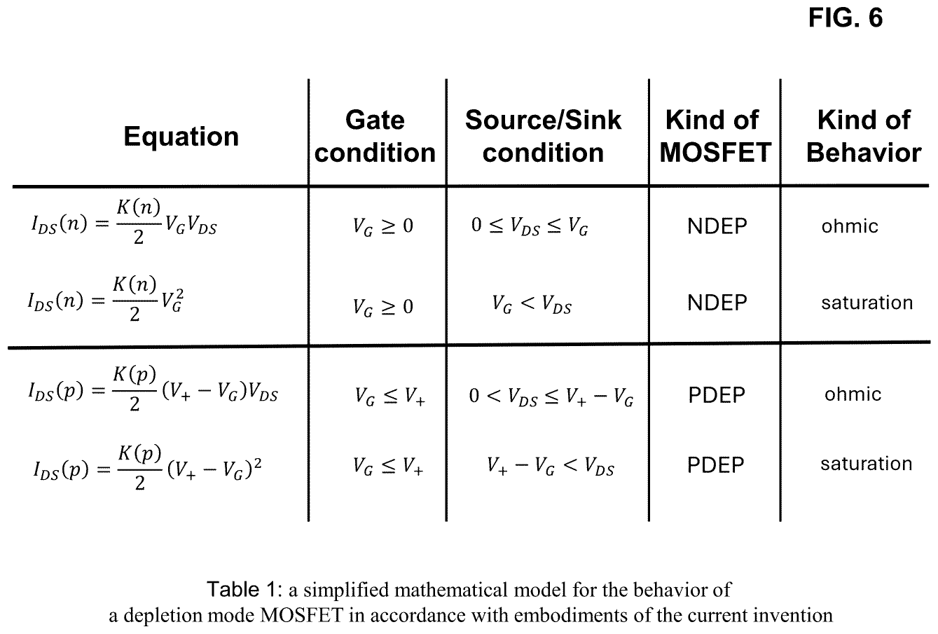

Table 1, illustrated in FIG. 6 is a simplified mathematical model for the behavior of a depletion mode MOSFET in accordance with embodiments of the current invention. The calculations are not intended to be exact, but give an approximate model to understand behavior of PDEP and an NDEP in accordance with embodiments of the current invention. The dielectric constat K(n) and K(p) for the NDEP and PDEP respectively is the dielectric constant of the gate insulator. Optionally, the thickness of the insulator and K value may be selected to inhibit tunnel leak through the gate.

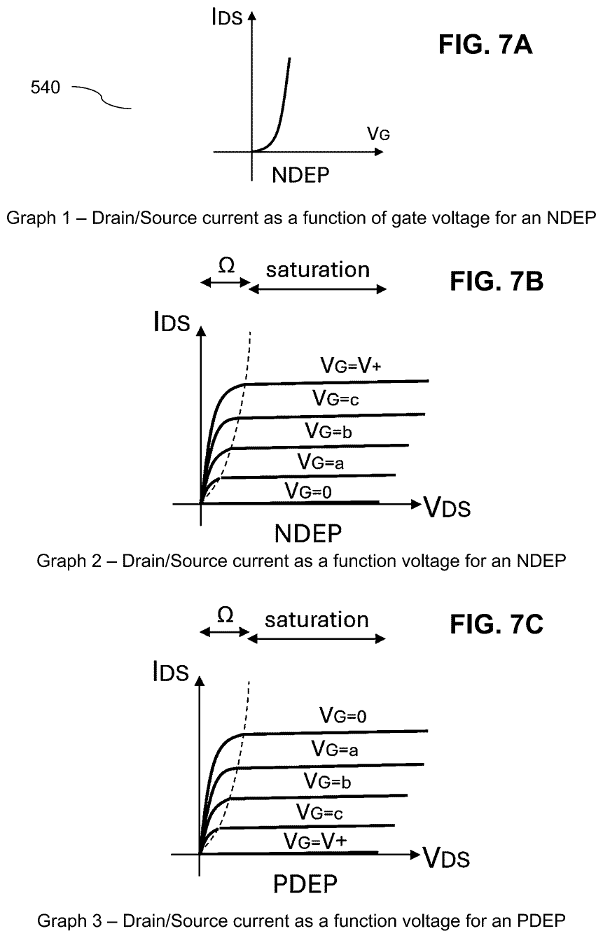

FIGS. 7A-7C are graphs illustrating behavior of depletion mode transistors in a predicted by the model of FIG. 6.

In some embodiments, the ohmic operation of the PDEP/NDEP (e.g., as illustrated in the left portions of FIGS. 7B and 7C labeled as Ω) may facilitate implementation of PDEP/NDEP single transistor pass gates (e.g., as illustrated in FIGS. 1B and 1C). A single transistor pass gate may considerable consequences for circuit design applications (e.g., replacing current two transistor pass gates in various application and/or facilitating reduction in size and/or improvement in behavior of various integrated circuits). The schematic symbol of NDEP/PDEP pass gate is illustrated in FIGS. 1B and 1C with all the 4 G, D, S, B terminals. Optionally, the drain and the source are connected to isolated bidirectional signals and/or the bulk may not be connected to any of them. Alternatively or additionally, a single transistor pass gates of the current invention may be used as large power switches. Optionally, separate bulk control may significantly reduce the leakage when the pass gate is OFF.

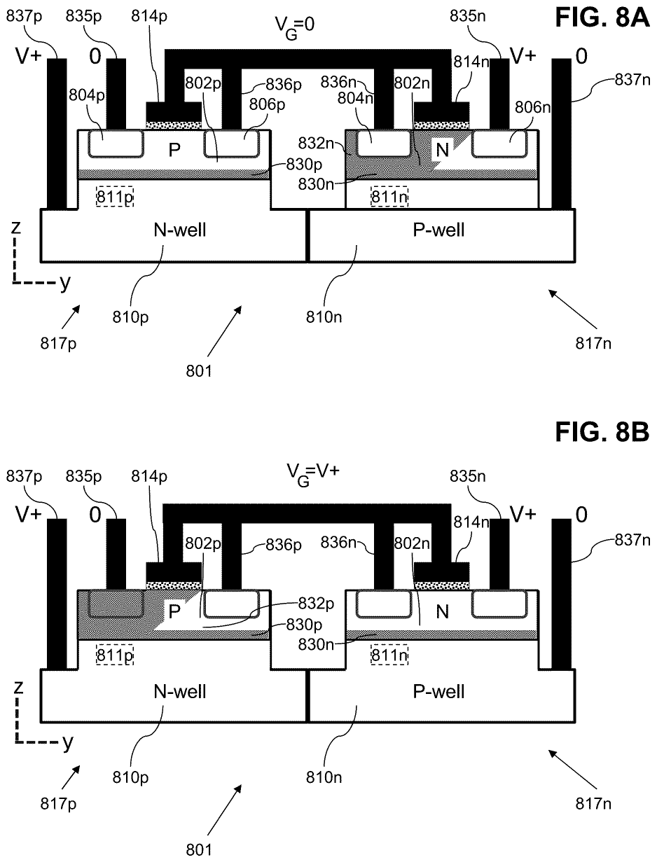

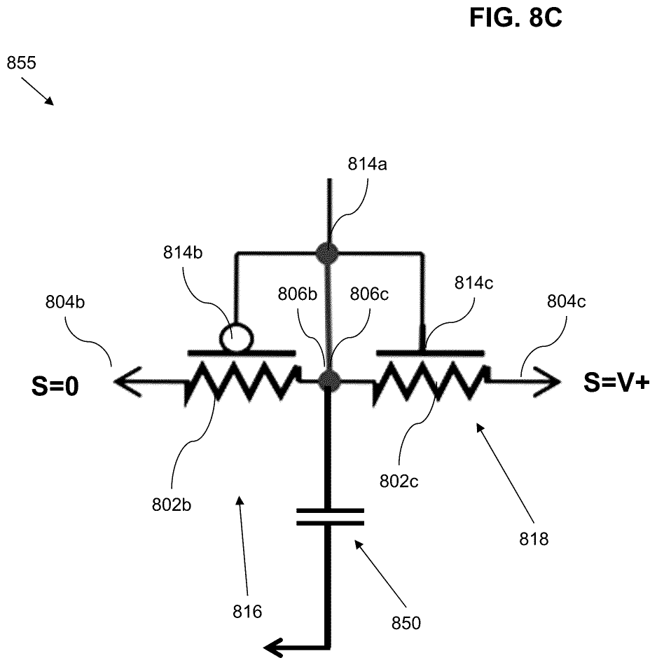

FIGS. 8A and 8B illustrate a 2-transistor retention element 801 in accordance with an embodiment of the current invention. Many conventional CMOS retention elements are based on 2 inverters back-to-back, with transistor count of 4. For example, the element 801 is a retention element 801 including only 2 transistors.

In some embodiments, the system includes one pull-down transistor (e.g., PDEP 817p) whose source 804p is fixed at V_{S}=0 and one pull-up transistor (e.g., NDEP 817n) whose source 804n is fixed at V_{S}=V+. The drain leads 836p and 836n and the gate leads 814p, 814n of both transistors are optionally shorted. Optionally, the pull-down transistor (e.g., PDEP 817p) is configured to be ON for a gate charge around 0 and the pull up transistor (e.g., NDEP 817n) is configured to be ON for a gate charge around V+ and the pull-down transistor (e.g., PDEP 817p) is configured to be OFF for a gate charge around V+ and the pullup transistor configured (e.g., NDEP 817n) to be OFF for a gate charge around 0. Optionally, the device is surrounded by an insulator. For example, the trench between the NDEP 217n and PDEP 217p may be insulated.

In some embodiments, the above charges and connections of the leads 835n, 835p, 836n, 836p and gates 814n and 814p and behavior of the pull-up transistor and pull-down transistor will cause the element 801 to act as a retention element with the following properties: The conduction is negligible between the source lead 835n of pull-up transistor and the source lead 835p of the pull-down transistor whether the gate voltage is near V_{G}=0 or near V_{G}=V+. Optionally, there is a base lead (e.g., 837n and 837p for the NDEP 817n and PDEP 817p respectively) used for controlling the biasing on the well.

The element 801 acts as a retention element remaining stable for gate voltage is near V_{G}=0 or near V_{G}=V+. 6. For example, when the initial condition is V_{G}=V+ at the shorted gates 814n and 814p drains 806n and 806p and leads 836n and 836p (e.g., as illustrated in FIG. 8B), the NDEP 817n is ON connecting the shorted lead 836n to the V+source lead 835n retaining the voltage of the shortened leads 836p and 836n and gates 814n and 814p at voltage V+, while the PDEP 817p is OFF. In some embodiments, when there is a small change in the voltage from the input condition V_{G}=V+, the output will tend to restore V_{G}=V+ at gates 814n and 814p drains 806p and 806n and leads 836p and 836n. For example, when the initial condition of V_{G}=0 at on the shorted output node leads 836n and 836p and drains 806n and 806p and gates 814n and 814p (e.g., as illustrated in FIG. 8A) the NDEP 817n is OFF, while the PDEP 817p is ON the output voltage V_{G} at gates 814n and 814p drains 806n 806p and leads 836p and 836n will restore to V_{G}=0 (‘0’).

In some embodiment, the element 801 has a metastable state. For example, when the initial condition of ½ V+ on the output node leads 836n and 836p and drains 806n and 806p and gates 814n and 814p with symmetrical pull-up and pull down. Metastability may be an undesired state where both transistors are stacked in max Ids saturation current.

In some embodiments, increasing the positive level of V+ may improve the CDEP element 801 performance. For example, upon raising the V+ value: when V+ is higher the cutoff is better, and the driving ability is better. Moreover, the gate capacitance is reduced due to decreasing the depletion capacitor which comes in series with the oxide gate capacitance.

In some embodiments, the 2-transistor retention element 801 will be made of two depletions FINFET's, for example as illustrated in FIGS. 2A, 2B and/or 4A-4C. For example, NDEP 817n may include a lower P layer 811n connected to the P-well 810n and/or an upper N-channel 802n. When the gate 814n has a V_{G}=V+ (e.g., FIG. 8B) an upper portion of the N-channel 802n may be open to conduction between a n-doped source 804n and drain 806n. Contact between the N channel 802n and the P well 810n and/or contact between the N channel 802n and the P dopped lower P layer 811n may result in a lower depleted portion 830n in the N channel 802n. When the gate 814n has a V_{G}=0 (e.g., FIG. 8A) the gate charge may deplete an upper portion of the N-channel 802n, which along with contact between the N channel 802n and the P well 810n and/or contact between the N channel 802n and the P dopped lower 811n may result in a depleted portion 832n and depleted portion 830n that join to block conduction in the N channel 802n.

For example, PDEP 817p may include an N-layer 811p connected to the N-well 810p and/or a P-channel 802p. When the gate 814p has a V_{G}=0 (e.g., FIG. 8A) the portion of the P-channel 802p that is close to the gate 814p may be open to conduction between a P-doped source 804p and drain 806p. Contact between the P-channel 802p and the N-well 810p and/or contact between the P-channel 802p and the P dopped N-layer 811p may result in a depleted portion 830p in the P-channel 802p near the N-well 810p and/or far from the gate 814p. When the gate 814p has a V_{G}=V+(e.g., FIG. 8B) the gate charge may deplete a portion of the P-channel 802p near the gate, which along with contact between the P-channel 802p and the N-well 810p and/or contact between the P-channel 802p and the N-dopped lower layer 811p may result in a depleted portion 832p and depleted portion 830p that join to block conduction in the P-channel 802p between the source 804p and drain 806p. For example, PDEP 817p may include a FINFET geometry (e.g., as described in FIGS. 2A-2C and/or FIGS. 4A-4C) and/or have another geometry.

For example, NDEP 817n may include a P-layer 811n connected to the P-well 810n and/or a N-channel 802n. When the gate 814n has a V_{G}=V+ (e.g., FIG. 8B) the portion of the N-channel 802n that is close to the gate 814n may be open to conduction between an N-doped source 804n and drain 806n. Contact between the N-channel 802n and the P-well 810n and/or contact between the N-channel 802n and the P-dopped P-layer 811n may result in a depleted portion 830n in the N-channel 802n near the P-well 810n and/or far from the gate 814n. When the gate 814n has a V_{G}=0 (e.g., FIG. 8A) the gate charge may deplete a portion of the N-channel 802n near the gate, which along with contact between the N channel 802n and the P well 810n and/or contact between the N-channel 802n and the P-dopped lower layer 811n may result in a depleted portion 832n and depleted portion 830n that join to block conduction in the N-channel 802n between the source 804n and drain 806n. For example, NDEP 817n may include a FINFET geometry (e.g., as described in FIGS. 2A-2C and/or FIGS. 4A-4C) and/or have another geometry.

In some embodiments this two-transistor element 801 may have the following properties. Whether the gate voltage is V_{G}=0 or V_{G}=V+ conduction is inhibited between source leads 835p and 835n and the gate voltage is stable.

FIG. 8C illustrates a symbolic transistor circuit 855 in accordance with an embodiment of the current invention. For example, FIG. 8C may be a symbolic representation of the structural device circuit from FIGS. 8A and/or 8B. The circuit includes a PDEP 816 an NDEP 818 and a capacitor 850. Optionally, the drain 806b of the PDEP 816 and the drain 806c of the NDEP 818 are short circuited to a common gate 814a lead and the gate 814b of the PDEP 816 and the gate 814c of the NDEP 818 and the capacitor 850. Optionally, the source 804b of the PDEP 816 is kept at S=0 and/or the source 804c of the NDEP 818 is kept at S=V+.

In some embodiments circuit 855 performs as a retention element. For example, for the initial condition of V+ on the output node (e.g., drain 806b, 806c) the NDEP 818 is ON (e.g., channel 802c is conductive), while the PDEP 816 is OFF (e.g., channel 802b blocks current). Optionally, under these conditions, the connection to the source 104c of the NDEP 818 will tend to restore the output to V+ (‘1’) when perturbed. For example, for an initial condition of 0 on the output node (e.g., drain 806b, 806c) the NDEP 818 is OFF (e.g., channel 802c blocks current), while the PDEP 816 is ON (e.g., channel 802b is conductive). Optionally, under these conditions, the connection to the source 804b of the PDEP 816 will tend to restore the output to 0 when perturbed. Whether the output node is at V+(where the PDEP 816 is OFF) or 0 (where the NDEP 818 if OFF) current will be blocked between source 804b and source 804c.

In some embodiments, for an initial condition somewhere between 0 and V+ which will be called ½ V+ on the output node there may be symmetrical pull-up and pull down. This may be labelled as a metastability state. It may happen in many retention elements. Optionally, a small dv towards V+ will drift the node to V+ and/or -dv towards 0 will drift the node toward 0. Metastability is sometimes considered an undesired state where both transistors are stacked in in saturation and/or current may flow between source 804b and source 804c.

In some embodiments, the raising positive level of V+ may improve the CDEP circuit 855 performance, Raising the V+ value may improve cutoff performance and/or the driving ability. Moreover, the gate capacitance may be reduced, for example due to decreasing the depletion capacitor which comes in series with the oxide gate capacitance.

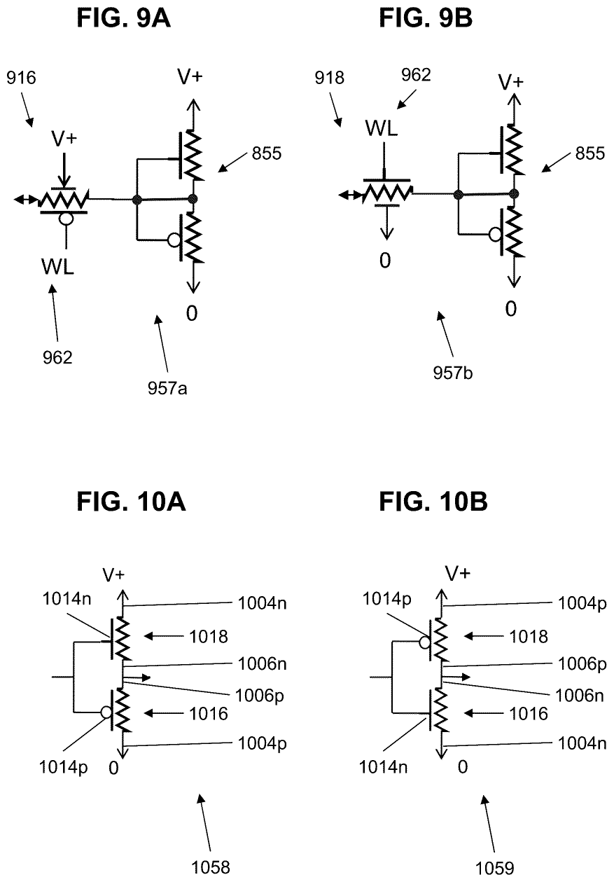

FIGS. 9A and 9B illustrate embodiments of a 3 transistor SRAM (Static Random Access Memory) in accordance with an embodiment of the current invention. For example, a single transistor pass gate (e.g., PDEP 916 for SRAM 957a and/or NDEP 918 for SRAM 957b) may be used as an access transistor to control read/write of data into the circuit (e.g., the word line 962 of the SRAM 957a, 957b is applied to the gate of the access transistor). For example, PDEP 116 and/or NDEP 118 may be used as the single transistor pass gate of PDEP 916 and/or NDEP 918 respectively. For example, a 2-transistor retention element circuit 855 may be used to store data (e.g., a bit of data).

FIG. 10A illustrates a two-transistor buffer in accordance with an embodiment of the current invention. For example, a buffer may have one NDEP 1018 pull-up and one PDEP 1016 pull down. Optionally, the gate 1014n of the NDEP 1018 may be shorted to the gate 1014p of the PDEP 1016 and/or the drain 1006p of the PDEP 1016 may be shorted to the drain 1006n of the NDEP 1018. The source 1004n of the NDEP may be connected to a positive voltage V+ and/or The source 1004p of the PDEP may be connected to a zero voltage 0. This reduces the transistor count compared to many conventional buffers having 4 transistors (e.g., 2 inverters). The number of inverters repeaters for long line of convention buffers may be constrained to be even. In some embodiments of the current invention a line of inverter repeaters may utilize any number of buffers.

FIG. 10B illustrates a two-transistor inverter in accordance with an embodiment of the current invention. For example, an inverter may have one NDEP 1018 pull-down and one PDEP 1016 pull up. Optionally, the gate 1014n of the NDEP 1018 may be shorted to the gate 1014p of the PDEP 1016 and/or the drain 1006p of the PDEP 1016 may be shorted to the drain 1006n of the NDEP 1018. The source 1004n of the NDEP may be connected to a positive voltage V+ and/or the source 1004p of the PDEP may be connected to a zero voltage 0. This reduces the transistor count compared to many conventional buffers having 4 transistors (e.g., 2 inverters). The number of inverters repeaters for long line of convention buffers may be constrained to be even. In some embodiments of the current invention a line of inverter repeaters may utilize any number of buffers.

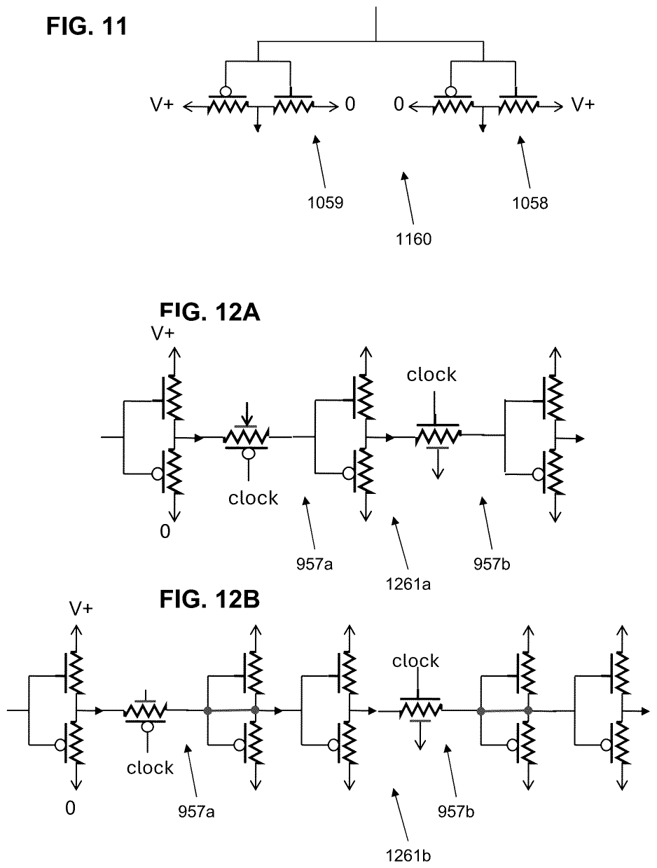

FIG. 11 illustrates a four-transistor single to differential 1160 schematic in accordance with an embodiment of the current invention. For example, the single to differential 1160 can take the form of buffer 1058 and inverter 1059. One or both of the buffer and/or the inverter may have use depletion transistors as described herein. This may reduce the transistor count over conventional circuits. For the differential 1160 the inverter may be non-leaky. For example, the NDEP 1018 may have zero current while the gate is zero. For example, the PDEP may have zero current while the gate is V+. In some embodiments, the inverter and/or the buffer may serve as elementary ingredients of an amplifier. For example, if the inverter or the buffer has an input small signal around ½ V+ then both PDEP&NDEP will be forced into saturation with a large, small signal amplification. Keeping a DC gate of ½ V+ for amplifier transistors, may facilitate saturation and/or proper linearity of the amplifier. This may apply for differential amplifiers as well.

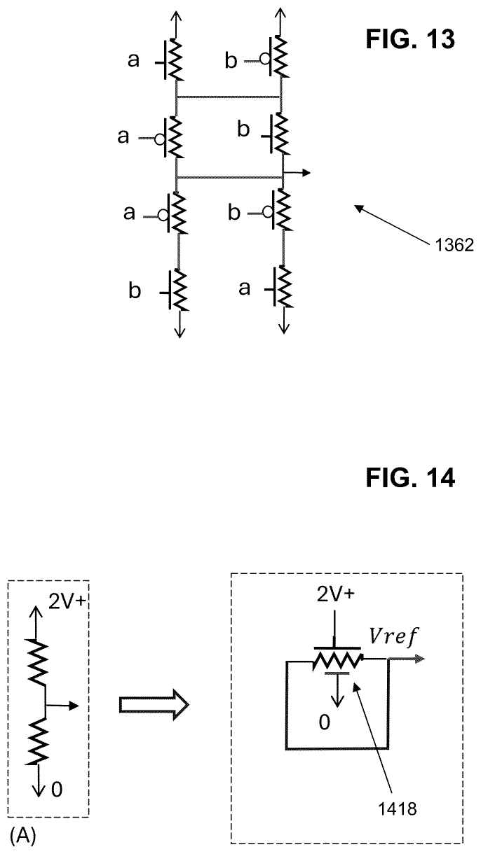

FIGS. 12A and 12B illustrates a dynamic D Flip Flop (DFF 1261a) compact D Flip Flop (D-FF 1261b) in accordance with embodiments. For example, the D-FF includes two latches each consisting of a pair of cross-coupled inverters. For example, the inverters may use a PDEP and/or NDEP as described herein to reduce the transistor count. For example, a D-FF may include two 3 transistor SRAM cells (e.g., as illustrated in FIGS. 9A and/or 9B e.g., SRAM 957a, 957b):
FIG. 13 illustrates an XNOR gate 1362 in accordance with an embodiment of the current invention. In some embodiments, the 0 cut off in NDEP gate and/or the V+ cut off in PDEP gate facilitates a simple approach of complex gates realization. For example, the XNOR gate 1362 may be realized without inverters on the inputs, thus input to output delays may equal and/or reduced.

In some embodiments, an intermediate (V+) bias may be controlled using a voltage divider. Two kinds of dividers (A, B) are marked in FIG. 14.

FIG. 14 illustrates a type A voltage divider in accordance with an embodiment of the current invention. Optionally, a type A may be routed only towards gate oxide in a static manner with negligible AC current. Optionally, a type A can be made of capacitors. For example, in FIG. 14B such a type A voltage divider is realized with a single NDEP 1418 transistor e.g., having a geometry of Cox/(Cox+Cdepletion). Optionally the value of Vref is a function of the gate area.

It is expected that during the life of a patent maturing from this application many relevant technologies will be developed and the scope of the terms is intended to include all such new technologies a priori.

As used herein the term “about” refers to ±10%

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween. When multiple ranges are listed for a single variable, a combination of the ranges is also included (for example the ranges from 1 to 2 and/or from 2 to 4 also includes the combined range from 1 to 4).

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. An N-channel depletion mode transistor comprising:
a P-doped substrate;
a fin protruding from said P-doped substrate said fin including
a P-doped base layer in contact with the P-doped substrate a N doped channel in contact with the P-doped base;
a gate in proximity to an intermediate location on the N-doped channel and electrically insulated from the N-doped channel;
a source in electrical contact with the N-doped channel on a first side of said intermediate location and a drain in electrical contact with the N-doped channel on a second side of said intermediate location, opposite first side.

2. The N-channel depletion mode transistor of claim 1, wherein a plurality of said fins are arranged in parallel on a chip.

3. The N-channel depletion mode transistor of claim 1, wherein for Vb=Vg=0 the transistor is in an OFF state wherein Vg is gate voltage, and Vb is P-doped substrate voltage.

4. The N-channel depletion mode transistor of claim 3, where in the OFF state there is negligible current between the source and the drain for a positive voltage potential 0<V+<Vbd between the source and the drain wherein 0<Vs≠Vd<V+ and Vbd is breakdown voltage, Vs is Source voltage, Vd is Drain voltage.

5. The N-channel depletion mode transistor of claim 4, wherein for Vg=V+ the N-doped channel depletion mode transistor is in an ON state.

6. The N-channel depletion mode transistor of claim 5, wherein a resistance to electrical current between the source and the drain in the OFF state is at least 10\hat{ }4 times a resistance to electrical current between the source and the drains in the ON state.

7. The N-channel depletion mode transistor of claim 1, wherein the N-channel mode transistor is configured to function as a single-transistor pass gate.

8. A MOFSET circuit where Vds is a voltage potential between 0 and V+ and less than
Vbd comprising:
a first transistor configured to be in an ON state for gate voltage of the first transistor V1g=V+ and an OFF state for V1g=0 and to have a break down voltage greater than V+;
a second transistor configured to in an ON state for a gate voltage of the second transistor V2g=0 and an OFF state V2g=V+ and to have a break down voltage greater than V+.

9. The MOFSET circuit of claim 8, where the circuit is configured as a two-transistor buffer.

10. The MOFSET circuit of claim 8, where the circuit is configured as a two-transistor inverter.

11. The MOFSET circuit of claim 8, where the circuit is configured as a three-transistor SRAM cell.

12. The MOFSET circuit of claim 8, where the circuit is configured as an eight-transistor dynamic DFF.

13. The MOFSET circuit of claim 8, where the circuit is configured as an twelve-transistor static DFF.

14. The MOFSET circuit of claim 8, where the circuit is configured as a two-transistor retention element.

15. The MOFSET circuit of claim 8, wherein the first and second transistors are depletion mode MOFSETS.

16. The MOFSET circuit of claim 15, wherein the first and second transistors are FINFETs.

17. The MOFSET circuit of claim 8, wherein the first transistor is an NDEP and the second transistor is an PDEP.

18. A method of building a MOFSET circuit where Vds is a voltage potential between 0 and V+ and less than Vbd comprising:
supplying a first transistor configured to be in an ON state for gate voltage of the first transistor V1g=V+ and an OFF state for V1g=0 and to have a break down voltage greater than V+;
supplying a second transistor configured to in an ON state for a gate voltage of the second transistor V2g=0 and an OFF state V2g=V+ and to have a break down voltage greater than V+.

19. The method of claim 18, further comprising:
building a two-transistor buffer by
shorting a gate of said first transistor to a gate of said second transistor as an input lead,
shorting a drain of said first transistor to a drain of said second transistor as an output lead,
connecting a source of said first transistor to a V+ voltage and
connecting a source of said second transistor to a 0 voltage.

20. The method of claim 17,
building a two-transistor inverter by
shorting a gate of said first transistor to a gate of said second transistor as an input lead,
shorting a drain of said first transistor to a drain of said second transistor as an output lead,
connecting a source of said first transistor to a 0 voltage and
connecting a source of said second transistor to a V+ voltage.

21. The method of claim 18, further comprising:
building a two-transistor retention element by
shorting the gates and drains of the first and second transistors together
supplying a voltage of V+ to a source lead of the first transistor and
supplying a voltage of 0 to a source lead of the second transistor.
